(19) United States
(12) Patent Application Publication
(10) Pub. No.: US 2017/0310328 A1
(43) Pub. Date: Oct. 26, 2017

(54) SIGNAL GENERATION CIRCUIT AND SIGNAL GENERATION METHOD

(71) Applicant: CANON KABUSHIKI KAISHA, Tokyo (JP)

(72) Inventor: Koji Ishibashi, Tokyo (JP)

(21) Appl. No.: 15/491,552

(22) Filed: Apr. 19, 2017

(30) Foreign Application Priority Data
Apr. 21, 2016 (JP) 2016-085431

(51) Int. Cl. H03L 7/089; H03L 7/099; H03L 7/093

(52) U.S. Cl. CPC H03L 7/0891; H03L 7/093; H03L 7/099

(57) ABSTRACT

A signal generation circuit comprises a VCO configured to generate a signal with a frequency corresponding to a control voltage; a divider configured to generate a divided signal by dividing the frequency of the signal generated by the VCO; a phase comparator configured to compare a reference clock signal generated by a reference oscillator and the divided signal generated by the divider; a charge pump configured to output a current corresponding to a comparison result of the phase comparator; a loop filter configured to generate a voltage corresponding to the current output by the charge pump; a switched capacitor filter configured to generate, by sampling the voltage generated by the loop filter, a control voltage of the VCO in a steady state; and an initial-value provision circuit configured to provide an initial value of the control voltage of the VCO.

### BACKGROUND OF THE INVENTION

### Field of the Invention

The present invention relates to a signal generation circuit and a signal generation method.

### Description of the Related Art

A clock generation circuit such as PLL (Phase Locked Loop) or CDR (Clock and Data Recovery) for frequency conversion of a reference clock is used in a variety of communication devices and LSIs. In recent years, the speed of data transmission and LSI signal processing has increased, and further reduction of jitter than conventionally achieved is required for a clock generated by the clock generation circuit. A reference leak, in which a reference clock for phase synchronization causes a control signal of a voltage controlled oscillator (to be referred to as a VCO hereinafter) to fluctuate, can be raised as one of the causes of jitter generation in the clock generation circuit. In order to suppress the reference leak, there is proposed a method in which the control voltage of the VCO is passed through a filter such as a notch filter or a low-pass filter. However, such a filter is often configured from passive elements such as resistors and capacitors, and the reference leak may not be sufficiently suppressed since the band can fluctuate due to the influence of a semiconductor process variation.

As one technique of suppressing the band fluctuation of a filter in the clock generation circuit, Japanese Patent Laid-Open No. 6-291644 proposes a switched capacitor filter (to be referred to as an SCF hereinafter)-type filter in which a filter band is determined by using only a plurality of capacitance ratios and capacitance switching frequencies. A method using the SCF-type filter is advantageous in that the filter band does not fluctuate since the relative ratio of capacitances does not fluctuate against comparatively large variation between chips/variation between semiconductor wafers.

However, initial charges are not provided in the method disclosed in Japanese Patent Laid-Open No. 6-291644. Hence, if the VCO is not oscillating in the initial state, the control voltage of the VCO is fixed to low level and may not be able to stably oscillate.

In addition, Japanese Patent Laid-Open No. 8-288845 discloses that an initial voltage of the control voltage of a VCO is applied in a clock generation circuit. In this clock generation circuit, a plurality of initial voltages are prepared in correspondence with a plurality of types of frequency changes of a reference signal to be input. However, although this clock generation circuit includes an LPF (loop filter) 2, neither a low-pass filter nor a switched capacitor is used.

### SUMMARY OF THE INVENTION

An aspect of the present invention provides a signal generation technique that can start stable oscillation or can shorten the time until phase lock in a signal generation circuit using an SCF-type filter.

One aspect of the present invention includes the following arrangement. A signal generation circuit comprising: a voltage controlled oscillator configured to generate a signal with a frequency corresponding to a control voltage; a divider configured to generate a divided signal by dividing the frequency of the signal generated by the voltage controlled oscillator; a phase comparator configured to compare a reference clock signal generated by a reference oscillator and the divided signal generated by the divider; a charge pump configured to output a current corresponding to a comparison result of the phase comparator; a loop filter configured to generate a voltage corresponding to the current output by the charge pump; a switched capacitor filter configured to generate, by sampling the voltage generated by the loop filter, a control voltage of the voltage controlled oscillator in a steady state; and an initial-value provision circuit configured to provide an initial value of the control voltage of the voltage controlled oscillator.

According to an exemplary aspect of the present invention, stable oscillation can be started or the time until phase lock can be shortened in a signal generation circuit using an SCF-type filter.

Further features of the present invention will become apparent from the following description of exemplary embodiments (with reference to the attached drawings).

### BRIEF DESCRIPTION OF THE DRAWINGS

The accompanying drawings, which are incorporated in and constitute a part of the specification, illustrate embodiments of the invention, and together with the description, serve to explain the principles of the invention.

FIGS. 1A and 1B are block diagrams each showing the function and the arrangement of a clock generation circuit;

FIGS. 2A and 2B are circuit diagrams each showing details of clock generation circuit members;

FIGS. 3A and 3B are graphs each showing filter frequency characteristics;

FIGS. 4A and 4B are flowcharts each showing the sequence of a series of processes in the clock generation circuit;

FIGS. 5A and 5B are timing charts corresponding to the respective flowcharts;

FIGS. 6A and 6B are block diagrams each showing the function and the arrangement of a clock generation circuit;

FIGS. 7A and 7B are flowcharts each showing the sequence of a series of processes in the clock generation circuit; and

FIGS. 8A and 8B are timing charts corresponding to the respective flowcharts.

### DESCRIPTION OF THE EMBODIMENTS

Embodiments of the present invention will be described below with reference to the accompanying drawings. However, embodiments of this disclosure are not limited to the following embodiments. The same reference numerals denote the same or almost the same constituent elements, members, and processes shown in the drawings, and a repetitive explanation will appropriately be omitted. Also, some members not important for explanation will be omitted from each drawing. In addition, a symbol denoted to a voltage, a current, or a resistance may be used as a symbol that represents a voltage value, a current value, or a resistance value as needed.

In an embodiment, a charge pump and a loop filter are provided on the feedback path of a PLL to convert a phase comparison result into a voltage. Furthermore, in a stage after the loop filter, a switched capacitor filter is provided to reduce or remove the switching noise generated in the charge pump. A sampling clock of this switched capacitor filter is provided from an output signal from PLL, that is, an output signal from a VCO. In an initial state immediately after power on to the PLL, the VCO uses, as a control signal, not the output from an SCF but another signal that has a higher and more stable potential. Hence, instability in the initial state due to the use of the SCF can be avoided.

### First Embodiment

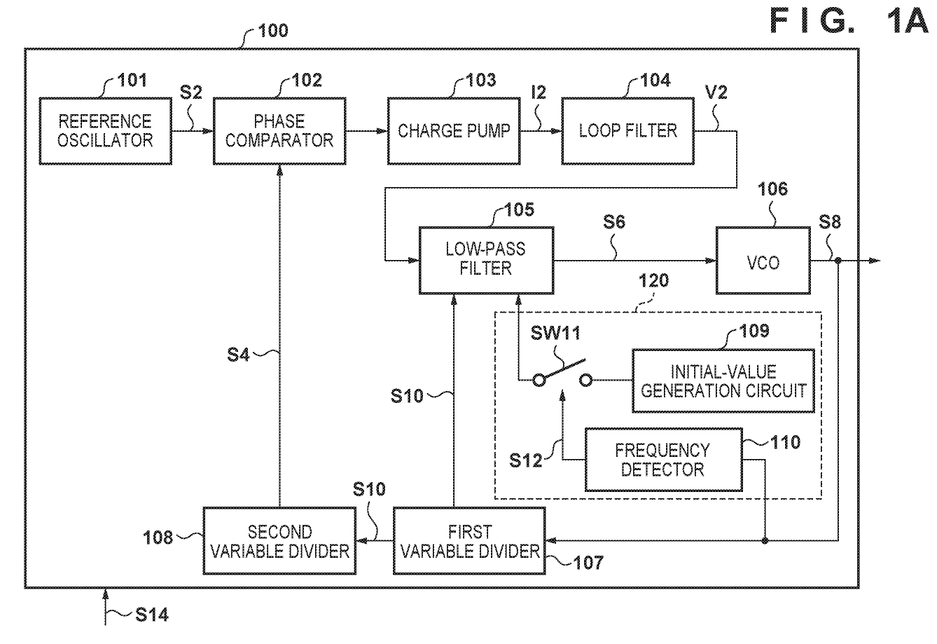

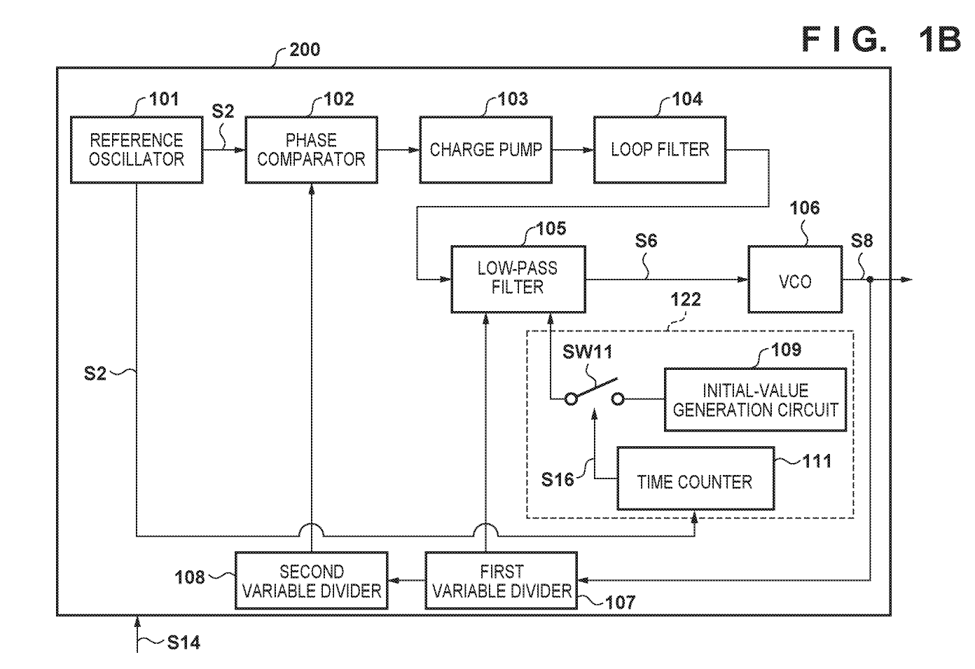

FIG. 1A is a block diagram showing the function and the arrangement of a clock generation circuit 100 according to the first embodiment. The clock generation circuit 100 includes a reference oscillator 101, a phase comparator 102, a charge pump 103, a loop filter 104, a low-pass filter 105, a VCO 106, a first variable divider 107, a second variable divider 108, and an initial-value provision circuit 120. The clock generation circuit 100 basically has a PLL arrangement that provides feedback to the VCO 106 by comparing the output from the VCO 106 with a reference clock.

The reference oscillator 101 generates a reference clock signal S2 and outputs the generated signal to the phase comparator 102. The phase comparator 102 compares the phase of the reference clock signal S2 generated by the reference oscillator 101 and the phase of a second divided signal S4 generated by the second variable divider 108 (to be described later). The charge pump 103 integrates the phase comparison result of the phase comparator 102 to output a comparison current 12 corresponding to the comparison result to the loop filter 104. The loop filter 104 generates a pump voltage V2 corresponding to the comparison current 12 output by the charge pump 103 and outputs the generated pump voltage to the low-pass filter 105. The loop filter 104 limits the output from the charge pump 103 to the loop band. The low-pass filter 105 is an SCF and generates a control signal S6 of the VCO 106 by suppressing or removing switching noise generated in the charge pump 103 from the output of the loop filter 104. The low-pass filter 105 outputs the generated control signal S6 to the VCO 106.

Note that the low-pass filter 105 may be replaced by another filter, for example a band elimination filter such as a notch filter, that has a function to remove the switching noise which is synchronized with the input clock of the phase comparator 102.

In a steady state, the VCO 106 obtains, as a control voltage, the voltage of the control signal S6 generated by the low-pass filter 105, generates an output signal S8 corresponding to the control voltage, and outputs the generated output signal. More specifically, the VCO 106 generates the output signal S8 having a frequency corresponding to the control voltage. The output signal S8 generated by the VCO 106 is output to the outside as an output signal of the clock generation circuit 100 and provided to the first variable divider 107 and the initial-value provision circuit 120. The first variable divider 107 generates a first divided signal S10 by dividing the frequency of the output signal S8 generated by the VCO 106 by a predetermined first frequency division number and outputs the generated first divided signal to the low-pass filter 105 and the second variable divider 108. The second variable divider 108 generates the second divided signal S4 by dividing the frequency of the first divided signal S10 obtained from the first variable divider 107 by a predetermined second frequency division number and outputs the generated second divided signal to the phase comparator 102.

Note that the first variable divider 107 and the second variable divider 108 are series-connected in the arrangement of this embodiment. However, it may be replaced by another arrangement that can provide a desired frequency clock signal to the low-pass filter 105 and the phase comparator 102. For example, a first variable divider for providing a clock signal to the low-pass filter 105 and a second variable divider for providing a clock signal to the phase comparator 102 may be provided in parallel. The first variable divider 107 and the second variable divider 108 may also be fixed dividers, respectively. Furthermore, although two dividers are used in this embodiment, the present invention is not limited to this. A single divider having both of these functions may be provided.

In the initial state of the operation of the clock generation circuit 100, the initial-value provision circuit 120 provides the initial value of the control current or control voltage for controlling the VCO 106. The initial-value provision circuit 120 includes an initial-value generation circuit 109, a frequency detector 110, and a provision switch SW11. The initial-value generation circuit 109 generates the initial value of the control voltage. The initial-value generation circuit 109 may be a constant voltage source that generates a predetermined voltage to serve as the initial value. The initial-value generation circuit 109 applies the generated initial value to one terminal of the provision switch SW11. The other terminal of the provision switch SW11 is connected to the low-pass filter 105. The frequency detector 110 functions as a control circuit that sets the provision switch SW11 to an OFF state in the steady state and turns on the provision switch SW11 during a period until the clock generation circuit 100 reaches the steady state. The frequency detector 110 turns on the provision switch SW11 upon powering on of the clock generation circuit 100. Subsequently, the frequency detector 110 monitors the frequency of the output signal S8 and turns off the provision switch SW11 when the frequency exceeds a predetermined threshold. This threshold may be set based on a nominal frequency of the clock generation circuit 100 or set based on the frequency of the output signal S8 in the steady state. The frequency detector 110 generates a frequency detection signal S12 and outputs the generated frequency detection signal to the control terminal of the provision switch SW11. In one example, the provision switch SW11 is turned on when the frequency detection signal S12 is asserted (that is, changes to high level), and the provision switch SW11 is turned off when the frequency detection signal is negated (that is, changes to low level). However, relationship between the level of the frequency detection signal S12 and the ON/OFF of the provision switch SW11 is not limited to this and may be another mode.

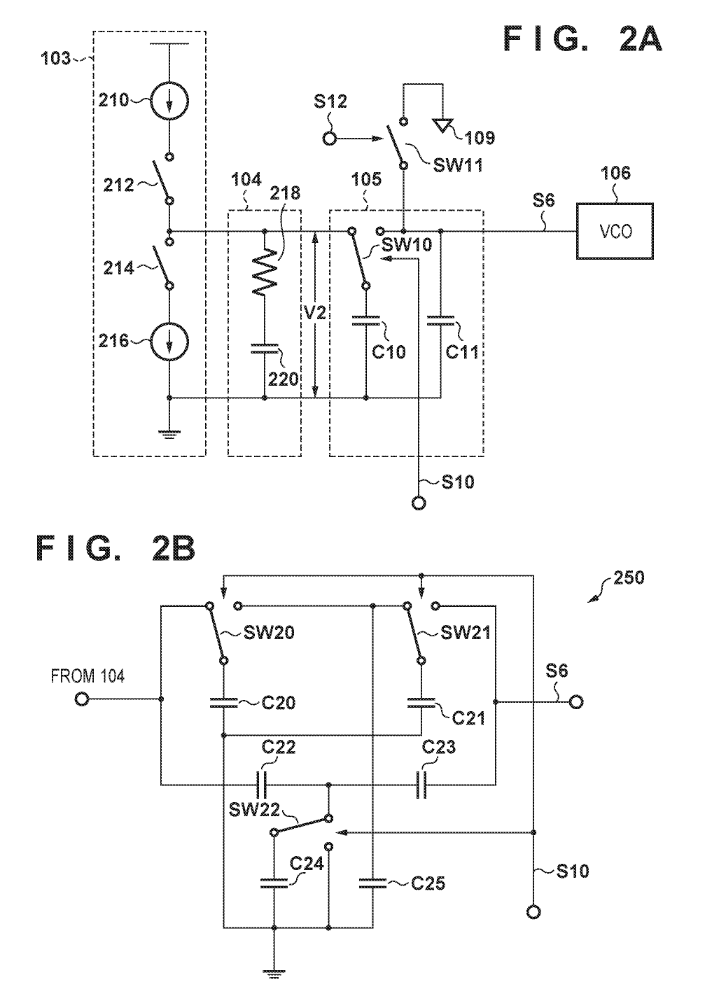

FIG. 2A is a circuit diagram showing the details of some members in FIG. 1A. FIG. 2A shows an example of the arrangement of an SCF-type low-pass filter 105 when the current output type charge pump 103 is used. The charge pump 103 includes a first constant current source 210, a first switch 212, a second switch 214, and a second constant current source 216. The first constant current source 210, the first switch 212, the second switch 214, and the second constant current source 216 are series-connected in this order. A power supply voltage is applied to one terminal of the first constant current source 210, and the other terminal is connected to one terminal of the first switch 212. One terminal of the second constant current source 216 is grounded, and the other terminal is connected to one terminal of the second switch 214. The first switch 212 and the second switch 214 are controlled by a signal representing the comparison result output from the phase comparator 102. The control of the first switch 212 and the second switch 214 may be implemented by a phase comparison technique used in a known PLL.

The loop filter 104 includes a first resistor 218 and a first capacitor 220. One terminal of the first resistor 218 is connected to a connection node between the other terminal of the first switch 212 and the other terminal of the second switch 214. The other terminal of the first resistor 218 is connected to one terminal of the first capacitor 220. The other terminal of the first capacitor 220 is grounded.

The low-pass filter 105 samples the pump voltage V2 generated by the loop filter 104 to generate the control voltage of the VCO 106 in the steady state. The sampling clock of this sampling is based on the output signal S8 generated by the VCO 106. More specifically, sampling is performed in accordance with the first divided signal S10 generated by dividing the frequency of the output signal S8.

The low-pass filter 105 includes a third switch SW10, a second capacitor C10, and a third capacitor C11. The third switch SW10 implements switching between a first state in which one terminal of the second capacitor C10 and one terminal of the first resistor 218 are connected and a second state in which one terminal of the second capacitor C10 and one terminal of the third capacitor C11 are connected. The first divided signal S10 is input to a control terminal of the third switch SW10, and the third switch SW10 is controlled by the first divided signal S10. For example, the third switch SW10 implements the first state when the first divided signal S10 is at high level and implements the second state when the first divided signal is at low level. The other terminals of the second capacitor C10 and the third capacitor C11 are grounded, respectively. The other terminal of the provision switch SW11 is connected to one terminal of the third capacitor C11, and their connection node is connected to a control signal input terminal of the VCO 106. The voltage of the connection node becomes the voltage of the control signal S6.

In the initial state immediately after the clock generation circuit 100 has been activated from a power down state, the VCO 106 does not generate a clock signal which has a sufficient frequency. Hence, if the third switch SW10 is driven using this clock signal, the frequency of the switching operation of the third switch SW10 becomes insufficient, and the voltage level of the control signal S6 of the VCO 106 becomes indefinite. If such an indefinite voltage level changes to a level of voltage equal to or less than that capable of oscillating the VCO 106, the VCO 106 will hold a state without oscillation. Therefore, in this embodiment, the initial voltage of the control voltage that is a voltage within the oscillation range of the VCO 106 is applied to the control signal input terminal of the VCO 106 via the provision switch SW11 in the initial state. This forces the oscillation of the VCO 106 to start. The initial value of the control voltage generated by the initial-value generation circuit 109 can be within a range in which a clock signal can be generated by the VCO 106. Alternatively, the initial value can be fixed near a level of the control signal S6 at the time of a lock operation of the clock generation circuit 100 to shorten the time required for lock in.

In the example of FIG. 2A, a case in which the connection node of the other terminal of the provision switch SW11 and one terminal of the third capacitor C11 is in the low-pass filter 105 has been described. However, the present invention is not limited to this. It may have another arrangement as long as the other terminal of the provision switch SW11 is connected to the control signal input terminal of the VCO 106. For example, the connection node of the output terminal of the low-pass filter 105 and the other terminal of the provision switch SW11 may be connected to the control signal input terminal of the VCO 106.

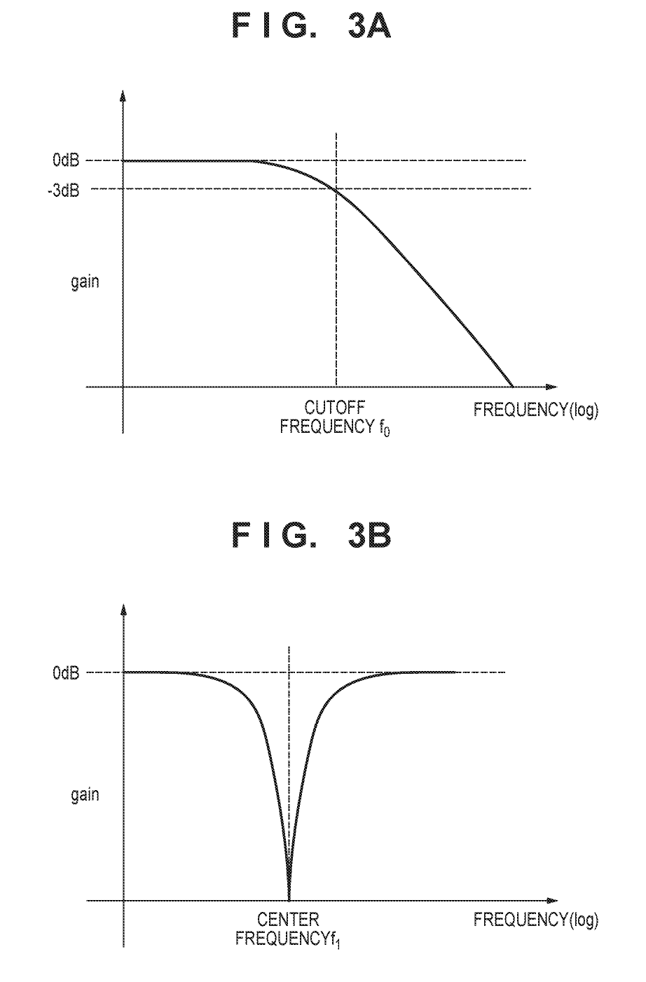

FIG. 3A is a graph showing the frequency characteristic of the SCF-type low-pass filter 105. The abscissa indicates a frequency representing a log, and the ordinate indicates a filter gain. In a case in which a parasitic element and surrounding influence can be ignored, the second capacitor C10, the third capacitor C11, and a switching frequency f_{SW} can be used to logically represent a cutoff frequency f₀ of the low-pass filter 105 by

$${f}_{0} = \frac{C 10}{C 11} {f}_{SW} \qquad ( 1 )$$

Noise removal can be performed by setting the cutoff frequency f₀ shown in the equation (1) to be lower than the noise frequency of a noise such as a reference leak. If a fixed frequency such as the output frequency of the reference oscillator 101 is used as the switching frequency f_{SW}, the cutoff frequency must be adjusted by only the second capacitor C10 and the third capacitor C11. Hence, there is low degree of freedom in capacitance value selection. Furthermore, for the capacitive element such as a capacitor, since the area and element variation are in a tradeoff relationship, the selectable capacitance values are also limited by element variation. To cope with this, in this embodiment, the output signal S8 of the VCO 106 or the first divided signal S10 obtained by dividing the frequency of the output signal S8 is used as the input clock. As a result, since the cutoff frequency f₀ can be adjusted using the switching frequency f_{SW} as well as the capacitance value, the freedom of capacitance value selection can be improved. The loop filter 104 and the low-pass filter 105 are connected in this order after the charge pump 103 in FIGS. 1A and 2A. However, the connection order of the loop filter 104 and the low-pass filter 105 may be reversed.

The operation of the clock generation circuit 100 having to the above arrangement will be described.

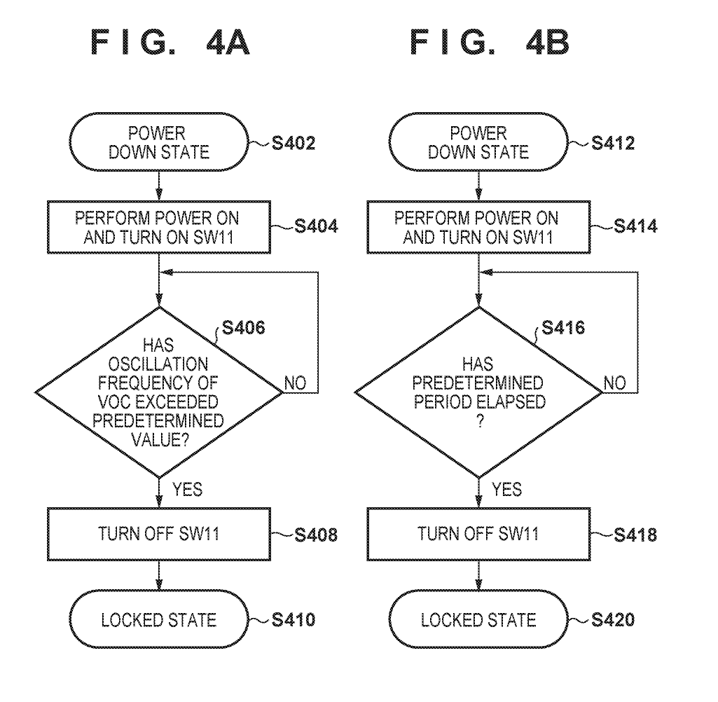

FIG. 4A is a flowchart showing the sequence of a series of processes in the clock generation circuit 100. The sequence shown in FIG. 4A corresponds to the arrangement in which the provision switch SW11 is controlled by detecting the frequency of the VCO 106. In step S402, the clock generation circuit 100 is in a power down state in which power is not supplied or the operation is stopped. In step S404, a power on signal S14 of the clock generation circuit 100 is asserted and power supply to the clock generation circuit 100 is started or the operation stop state is canceled, thereby changing the clock generation circuit 100 to the initial state. The clock generation circuit 100 turns on the provision switch SW11 upon asserting the power on signal S14. Note that it is sufficient as long as the power on of the clock generation circuit 100 and the turning on of the provision switch SW11 synchronously occur. It does not matter whether the operations occur simultaneously or if one of the operations occurs earlier.

The initial value of the control voltage is provided to the VCO 106 when the provision switch SW11 changes to the ON state. This changes the control voltage to a value capable of oscillation, and the output signal S8 of the VCO 106 changes to a clock signal. In step S406, the frequency detector 110 detects whether the frequency of the output signal S8 generated by the VCO 106, that is, the oscillation frequency of the VCO 106 has exceeded a predetermined value. If the oscillation frequency of the VCO 106 has exceeded the value, the clock generation circuit 100 turns off the provision switch SW11 in step S408. Otherwise, the clock generation circuit 100 repeats step S406. After a predetermined period has elapsed since the provision switch SW11 has been turned off, the clock generation circuit 100 changes to the steady state, that is, a locked state, in step S410.

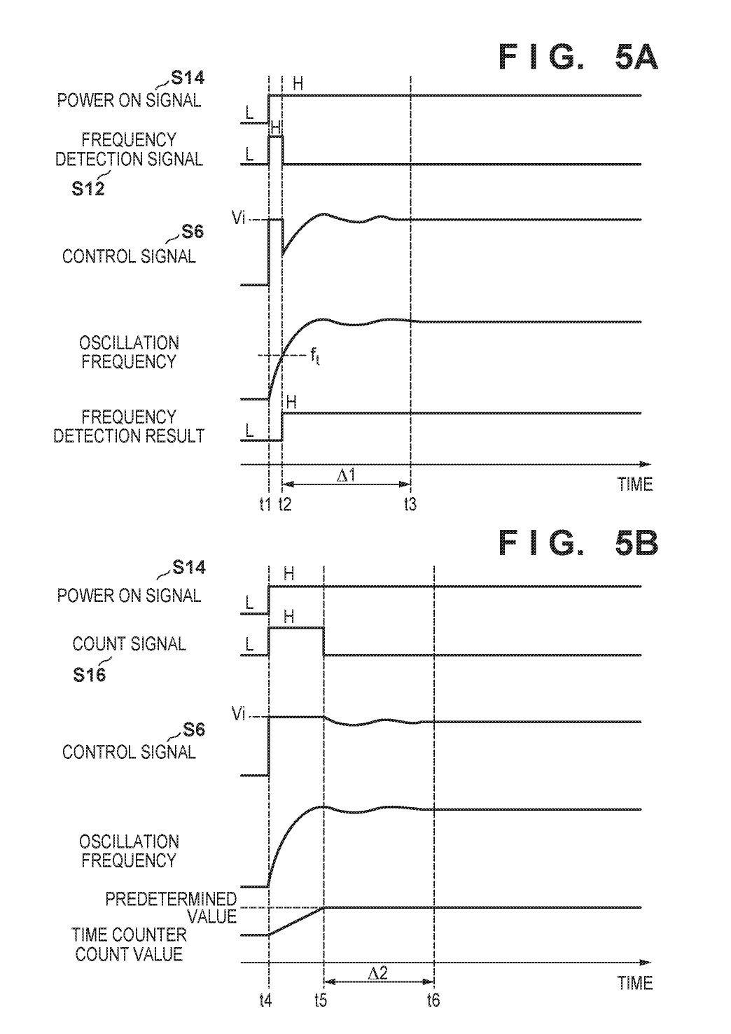

FIG. 5A is a timing chart corresponding to the flowchart shown in FIG. 4A. From the top in FIG. 5A, the power on signal S14, the frequency detection signal S12, the control signal S6, the oscillation frequency of the VCO 106, and the frequency detection result of the frequency detector 110 are shown. In FIG. 5A, the abscissa indicates a time, and the ordinate indicates a voltage level in the case of a signal and a frequency value in the case of a frequency. High level corresponds to ON and low level corresponds to OFF in each of the power on signal S14 of the clock generation circuit 100 and the frequency detection signal S12. The frequency detection result is a signal that changes to high level when the oscillation frequency of the VCO 106 is higher than a predetermined value fₜ and changes to low level when the oscillation frequency is lower than the predetermined value fₜ. The frequency detection result is generated in the frequency detector 110. The voltage level of the control signal S6 shows analog changes.

At time t1, the power on signal S14 of the clock generation circuit 100 changes to high level, and the frequency detection signal S12 also changes to high level accordingly. When the frequency detection signal S12 changes to high level, the provision switch SW11 is turned on, and an initial value Vᵢ of the control voltage is input to the VCO 106. The VCO 106 starts to oscillate upon receiving this initial value Vᵢ. At time t2, the oscillation frequency of the VCO 106 exceeds the predetermined value fₜ. Accordingly, the frequency detection result changes from low level to high level, and the frequency detection signal S12 changes from high level to low level. When the frequency detection signal S12 changes to low level, the provision switch SW11 is turned off, and the supply of the initial value Vᵢ to the control signal S6 ends. From time t3, after a predetermined period Δ1 has elapsed from time t2, the output signal S8 settles to the locked state in which the signal is locked to a desired frequency and phase.

According to the clock generation circuit 100 of this embodiment, instead of the output from the SCF-type low-pass filter 105 which is indefinite in the initial state, an initial value generated in the initial-value generation circuit 109 can be supplied to the VCO 106 by arranging the initial-value provision circuit 120. Therefore, the activation operation of the VCO 106 form power on until the steady state can be stabilized. In addition, since the initial-value provision circuit 120 is configured to detect that the state comes close to the steady state and stop the supply of the initial value, the influence provided to the steady state due to the presence of the initial-value provision circuit 120 can be decreased or removed.

In the first embodiment, a case in which the initial-value provision circuit 120 detects the frequency of the output signal S8 has been described. However, the present invention is not limited to this. For example, the provision switch SW11 may be turned off after a predetermined time has elapsed since power on. Alternatively, the provision switch SW11 may be turned off when it is detected that the output signal S8 of the clock generation circuit 100 is locked. FIG. 1B is a block diagram showing the function and arrangement of a clock generation circuit 200 according to a first modification. The clock generation circuit 200 uses a time counter that measures a predetermined period to control the provision switch SW11. The clock generation circuit 200 includes the reference oscillator 101, the phase comparator 102, the charge pump 103, the loop filter 104, the low-pass filter 105, the VCO 106, the first variable divider 107, the second variable divider 108, and an initial-value provision circuit 122.

The initial-value provision circuit 122 has an arrangement in which the entity that controls the provision switch SW11 in the initial-value provision circuit 120 of the first embodiment has been replaced from the frequency detector 110 to a time counter 111. The time counter 111 turns on the provision switch SW11 upon power on of the clock generation circuit 200. The time counter 111 refers to the reference clock signal S2 generated in the reference oscillator 101 and counts the length of a period that has elapsed since the provision switch SW11 has been turned on. The time counter 111 turns off the provision switch SW11 when the length of the period obtained by the count exceeds a predetermined threshold. Note that in this modification, the reference clock signal S2 is obtained from the reference oscillator 101 to count the length of the period. However, the present invention is not limited to this, and another clock may be used.

FIG. 4B is a flowchart showing the sequence of a series of processes in the clock generation circuit 200. The sequence shown in FIG. 4B corresponds to an arrangement in which the provision switch SW11 is controlled by counting an ON period of the provision switch SW11 instead of detecting the frequency. In step S412, the clock generation circuit 200 is in a power down state of no power supply. In step S414, the power on signal S14 of the clock generation circuit 200 is asserted, power supply to the clock generation circuit 200 is started, and the clock generation circuit 200 is changed to the initial state. The clock generation circuit 200 turns on the provision switch SW11 upon asserting of the power on signal S14. Note that it is sufficient as long as the power on of the clock generation circuit 200 and the turning on of the provision switch SW11 synchronously occur. It does not matter whether the operations occur simultaneously or if one of the operations occurs earlier.

The initial value of the control voltage is provided to the VCO 106 when the provision switch SW11 changes to the ON state. This changes the control voltage to a value capable of oscillation, and the output signal S8 of the VCO 106 changes to a clock signal. In step S416, the clock generation circuit 200 determines whether a predetermined period has elapsed since the provision switch SW11 has changed to ON. For example, the time counter 111 starts counting when the provision switch SW11 is turned on. The time counter 111 determines that the predetermined period has elapsed when the count value reaches a predetermined value. The predetermined period is set to be longer than the time necessary for the VCO 106 to reach a sufficient oscillation frequency since the start of oscillation. If it is determined that the predetermined period has elapsed, the clock generation circuit 200 turns off the provision switch SW11 in step S418. In step S420, after a predetermined period has elapsed since the provision switch SW11 has been turned off, the clock generation circuit 200 changes to the steady state, that is, the locked state.

FIG. 5B is a timing chart corresponding to the flowchart shown in FIG. 4B. From the top in FIG. 5B, the power on signal S14, a count signal S16 that controls the provision switch SW11, the control signal S6, the oscillation frequency of the VCO 106, and the count value of the time counter 111 are shown. In FIG. 5B, the abscissa indicates a time, and the ordinate indicates a voltage level of a signal, a frequency, or a count value. High level corresponds to ON and low level corresponds to OFF for each of the count signal S16 and the power on signal S14 of the clock generation circuit 200. The voltage level of the control signal S6 shows analog changes.

At time t4, the power on signal S14 of the clock generation circuit 200 changes to high level, and the count signal S16 changes to high level accordingly. When the count signal S16 changes to high level, the provision switch SW11 is turned on, and the initial value Vᵢ of the control voltage is input to the VCO 106. The VCO 106 starts to oscillate upon receiving this initial value Vᵢ. In addition, the time counter 111 starts counting in response to the turning on of the provision switch SW11. At time t5, the count value of the time counter 111 reaches the predetermined value. The count signal S16 changes from high level to low level. The provision switch SW11 is turned off when the count signal S16 changes to low level, and the supply of the initial value Vᵢ to the control signal S6 ends. From time t6 and onward, after a predetermined period Δ2 has elapsed from time t5, the output signal S8 settles to the locked state in which the signal is locked to a desired frequency and phase.

The clock generation circuit 200 according to this first modification has the same effects as those of the clock generation circuit 100 according to the first embodiment.

In the first embodiment, a case using the SCF-type low-pass filter 105 has been described. However, the present invention is not limited to this. For example, an SCF-type notch filter may be used. FIG. 2B is a circuit diagram of a notch filter 250 arranged between the loop filter 104 and the VCO 106 in a clock generation circuit according to a second modification. The notch filter 250 includes a fourth switch SW20, a fifth switch SW21, a sixth switch SW22, a fourth capacitor C20, a fifth capacitor C21, a sixth capacitor C22, a seventh capacitor C23, an eighth capacitor C24, and a ninth capacitor C25.

The fourth switch SW20 implements the switching between a first state in which one terminal of the fourth capacitor C20 and one terminal of the sixth capacitor C22 are connected and a second state in which one terminal of the fourth capacitor C20 and one terminal of the ninth capacitor C25 are connected. The fifth switch SW21 implements switching between a first state in which one terminal of the fifth capacitor C21 and one terminal of the ninth capacitor C25 are connected and a second state in which one terminal of the fifth capacitor C21 and one terminal of the seventh capacitor C23 are connected. The sixth switch SW22 implements switching between a first state in which one terminal of the eighth capacitor C24 and the other terminal of the seventh capacitor C23 are connected and a second state in which one terminal of the eighth capacitor C24 and the other terminal of the ninth capacitor C25 are connected. One terminal of the sixth capacitor C22 is connected to the output of the loop filter 104. The other terminal of the fourth capacitor C20, the other terminal of the fifth capacitor C21, the other terminal of the eighth capacitor C24, and the other terminal of the ninth capacitor C25 are grounded. The other terminal of the sixth capacitor C22 is connected to the other terminal of the seventh capacitor C23. The signal generated in one terminal of the seventh capacitor C23 is output to the VCO 106 to serve as the control signal S6. The first divided signal S10 is input to each of the control terminals of the fourth switch SW20, the fifth switch SW21, and the sixth switch SW22. These switches are controlled by the first divided signal S10.

The frequency characteristic of the notch filter can be obtained by switching the fourth capacitor C20, the fifth capacitor C21, the eighth capacitor C24 in accordance with a frequency division clock of the first divided signal S10 provided from the first variable divider 107. FIG. 3B is a graph showing the frequency characteristic of the SCF-type notch filter 250. The abscissa indicates the frequency represented as a log, and the ordinate indicates a filter gain. A center frequency f₁ of the notch filter 250 is matched with the noise frequency of a noise such as a reference leak to decrease or remove the noise superimposed on the control signal S6 of the VCO 106. Note that at least one of the fourth capacitor C20, the fifth capacitor C21, and the eighth capacitor C24 can be replaced by a resistor.

The clock generation circuit according to this second modification has the same effects as those of the clock generation circuit 100 according to the first embodiment. In this manner, the technical idea according to the first embodiment is applicable to an SCF-type filter, and the filter arrangement is not limited to a low-pass filter or a notch filter.

### Second Embodiment

A case in which the initial-value provision circuit 120 generates the initial value has been described in the first embodiment. In the second embodiment, an initial-value provision circuit uses a voltage output from a loop filter 104 as an initial value.

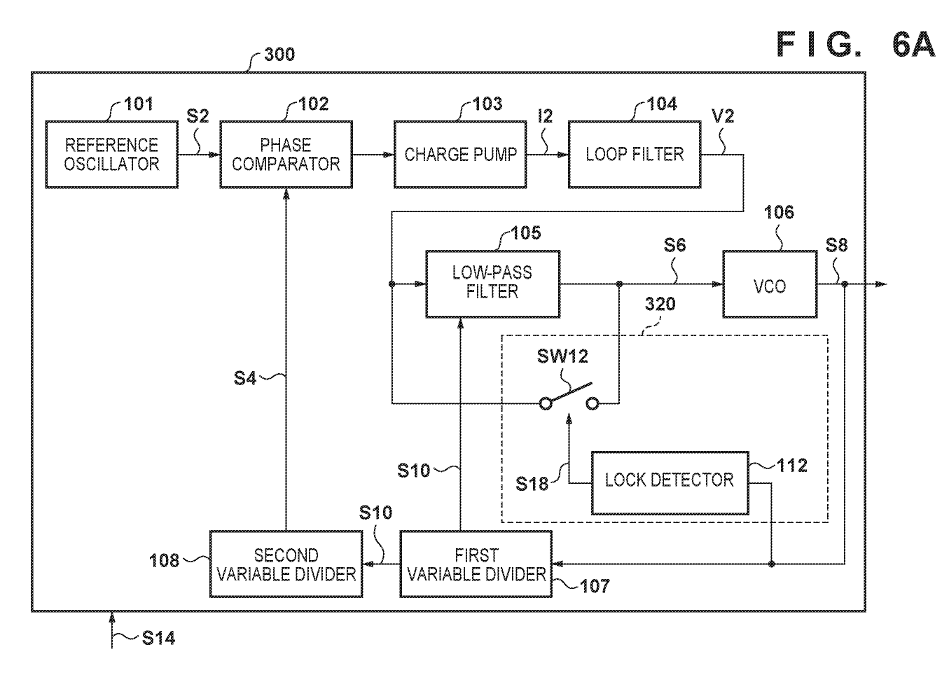

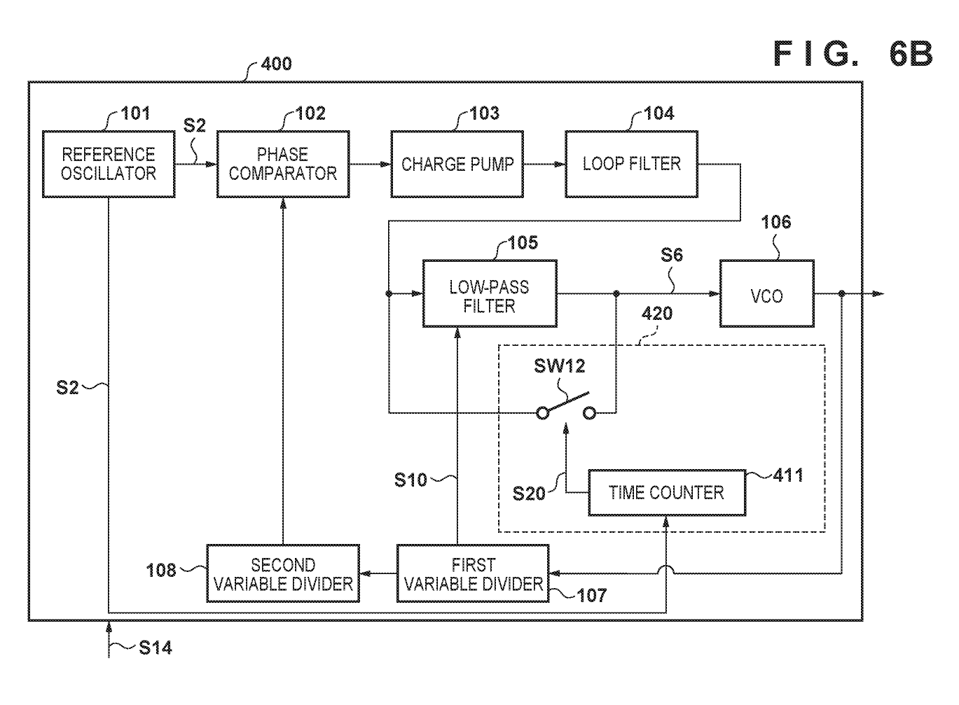

FIG. 6A is a block diagram showing the function and the arrangement of a clock generation circuit 300 according to the second embodiment. The clock generation circuit 300 includes a reference oscillator 101, a phase comparator 102, a charge pump 103, a loop filter 104, a low-pass filter 105, a VCO 106, a first variable divider 107, a second variable divider 108, and an initial-value provision circuit 320.

In an initial state of the operation of the clock generation circuit 300, the initial-value provision circuit 320 provides an initial value of the control current or control voltage for controlling the VCO 106. The initial-value provision circuit 320 includes a lock detector 112 and a bypass switch SW12. One terminal of the bypass switch SW12 is connected to an output terminal of the loop filter 104, and a pump voltage V2 is applied to the one terminal. The other terminal of the bypass switch SW12 is connected to the control signal input terminal of the VCO 106. In the initial state, the bypass switch SW12 operates so as to bypass the low-pass filter 105.

The lock detector 112 detects a locked state from the frequency of the output signal S8 of the VCO 106 and controls the bypass switch SW12 based on the detection result. The lock detector 112 turns on the bypass switch SW12 upon powering on of the clock generation circuit 300. Subsequently, the lock detector 112 monitors the output signal S8 and turns off the bypass switch SW12 upon detecting a frequency lock or a phase lock of the output signal S8. The lock detector 112 generates a lock detection signal S18 and outputs the generated lock detection signal to the control terminal of the bypass switch SW12.

In the arrangement shown in FIG. 6A, when the clock generation circuit 300 is activated from a power down state, the output from the SCF-type low-pass filter 105 becomes indefinite since the oscillation frequency of the VCO 106 is insufficient in the initial state. Hence, the bypass switch SW12 is turned on to bypass the low-pass filter 105 at the start of operation to help the oscillation of the VCO 106. The lock detector 112 determines whether the clock generation circuit 300 is locked and cancels the bypass when it is locked. Note that instead of the lock detector 112, the frequency detector 110 described in the first embodiment may be used to turn off the bypass switch SW12 when the frequency of the output signal S8 exceeds a threshold.

The operation of the clock generation circuit 300 having the above arrangement will be described.

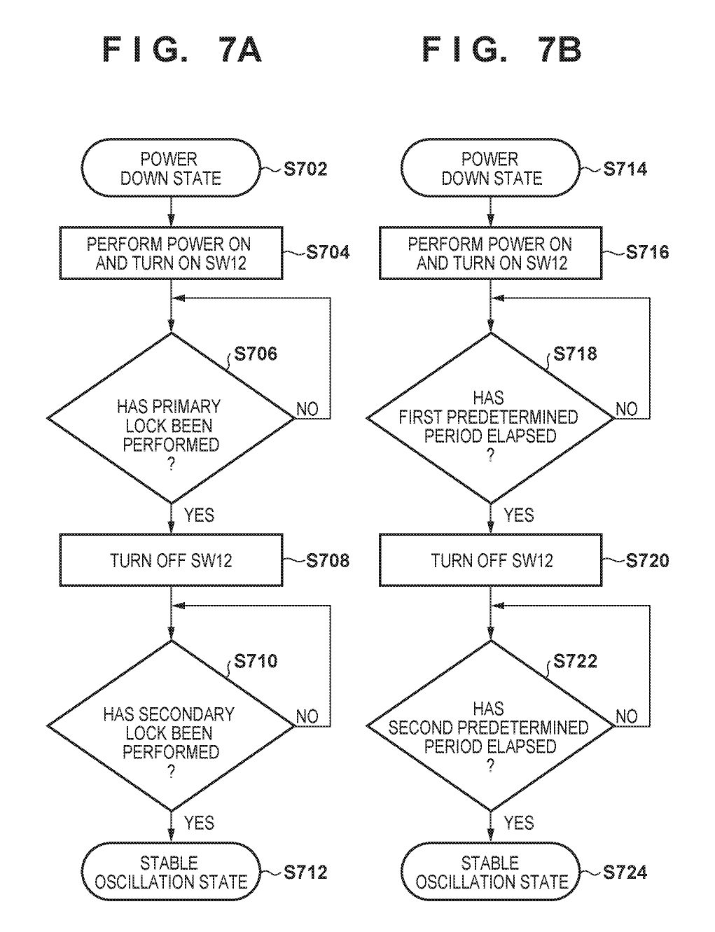

FIG. 7A is a flowchart showing the sequence of a series of processes in the clock generation circuit 300. The sequence shown in FIG. 7A corresponds to an arrangement in which the bypass switch SW12 is controlled by detecting the locked state of the clock generation circuit 300. In step S702, the clock generation circuit 300 is in the power down state of no power supply. In step S704, a power on signal S14 of the clock generation circuit 300 is asserted, power supply to the clock generation circuit 300 is started, and the clock generation circuit 300 changes to the initial state. The clock generation circuit 300 turns on the bypass switch SW12 upon asserting of the power on signal S14. Note that it is sufficient as long as the power on of the clock generation circuit 300 and the turning on of the bypass switch SW12 synchronously occur. It does not matter whether the operations occur simultaneously or if one of the operations occurs earlier.

When the bypass switch SW12 changes to the ON state, a loop operation having a form in which the low-pass filter 105 is bypassed becomes effective. The control voltage of the VCO 106 changes, and the output signal S8 of the VCO 106 changes to a clock signal. In step S706, the clock generation circuit 300 performs a primary determination to determine whether the frequency of the output signal S8 generated by the VCO 106 has reached a desired frequency. If the desired frequency has been reached, the clock generation circuit 300 determines that the primary lock has been implemented and turns off the bypass switch SW12 in step S708. Otherwise, the clock generation circuit 300 repeats steps S706 until the frequency is locked.

When the bypass switch SW12 is turned off in step S708, the frequency fluctuates due to switching noise. Hence, in step S710, the clock generation circuit 300 performs a secondary determination to determine again whether the frequency of the output signal S8 generated by the VCO 106 has reached the desired frequency. Note that if the frequency fluctuation of the VCO 106 is small or if it is unnecessary to confirm whether the clock generation circuit 300 is locked, the lock confirmation process in step S710 need not be performed. After the secondary lock has been confirmed in step S710, the clock generation circuit changes to a steady state, that is, a stable oscillation state of the VCO 106 in step S712. Note that although a frequency is used to detect the locked state in the second embodiment, a phase may be used to detect a phase lock in addition to or alternatively to detection by the frequency.

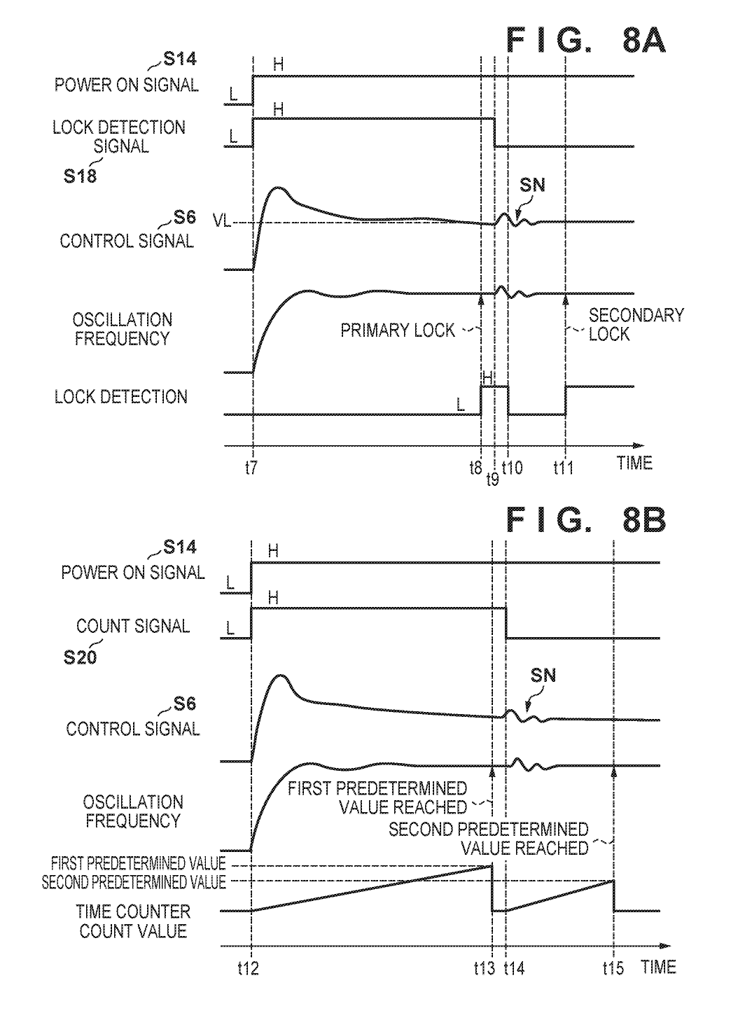

FIG. 8A is a timing chart corresponding to the flowchart shown in FIG. 7A. From the top in FIG. 8A, the power on signal S14, the lock detection signal S18, a control signal S6, the oscillation frequency of the VCO 106, and a lock detection result in the lock detector 112 are shown. In FIG. 8A, the abscissa indicates a time, and the ordinate indicates a signal voltage level or frequency. High level corresponds to ON and low level corresponds to OFF in each of the power on signal S14 of the clock generation circuit 300 and the lock detection signal S18. The lock detection result is a signal that changes to high level when the locked state of the output signal S8 is being detected and changes to low level during other periods. The lock detection result is generated in the lock detector 112. The voltage level of the control signal S6 shows analog changes.

At time t7, the power on signal S14 of the clock generation circuit 300 changes to high level, and the lock detection signal S18 also changes to high level accordingly. When the lock detection signal S18 changes to high level, the bypass switch SW12 is turned on, and the pump voltage V2 generated in the loop filter 104 is input as a control voltage to the VCO 106. The VCO 106 starts to oscillate upon receiving this control voltage. At time t8, the voltage of the control signal S6, that is, the control voltage is asymptotic to a predetermined lock time voltage V_{L}, and the clock generation circuit 300 detects the primary lock. Subsequently, at time t9, the lock detection signal S18 changes from high level to low level. When the lock detection signal S18 changes to low level, the bypass switch SW12 is turned off, and the bypassing of the low-pass filter 105 ends. Due to the influence of a switching noise SN which is superimposed on the control signal S6 when the bypass switch SW12 is turned off, it changes to a state in which no lock is detected at time t10. When the switching noise SN settles at time t11, the clock generation circuit 300 detects the secondary lock.

The clock generation circuit 300 according to the second embodiment has the same effects as those of the clock generation circuit 100 according to the first embodiment. Additionally, in the second embodiment, in order to prevent an indefinite output from the SCF-type low-pass filter 105, the VCO 106 is controlled by bypassing the low-pass filter 105 by the bypass switch SW12 at the start of the operation of the VCO 106. Although it may take more time to reach a frequency/phase lock in the second embodiment than in the first embodiment, the circuit can be downsized since an initial-value generation circuit need not be arranged.

In the second embodiment, a case in which the initial-value provision circuit 320 detects the locked state of the output signal S8 has been described. However, the present invention is not limited to this. For example, after a predetermined period has elapsed, the bypass switch SW12 may be turned off. FIG. 6B is a block diagram showing the function and the arrangement of a clock generation circuit 400 according to a third modification. The clock generation circuit 400 controls the bypass switch SW12 by using a time counter that measures the predetermined period. The clock generation circuit 400 includes the reference oscillator 101, the phase comparator 102, the charge pump 103, the loop filter 104, the low-pass filter 105, the VCO 106, the first variable divider 107, the second variable divider 108, and an initial-value provision circuit 420.

The initial-value provision circuit 420 has an arrangement in which the entity that controls the bypass switch SW12 in the initial-value provision circuit 320 of the second embodiment has been replaced from the lock detector 112 to a time counter 411. The time counter 411 turns on the bypass switch SW12 upon powering on of the clock generation circuit 400. The time counter 411 refers to the reference clock signal S2 generated by the reference oscillator 101 and counts the length of the period that has elapsed since the bypass switch SW12 has been turned on. The time counter 411 turns off the bypass switch SW12 when the period length obtained by the count exceeds a predetermined threshold. Note that in the third modification, a reference clock signal S2 is obtained from the reference oscillator 101 to count the length of the period. However, the present invention is not limited to this, and another clock may be used.

FIG. 7B is a flowchart showing the sequence of a series of processes in the clock generation circuit 400. The sequence shown in FIG. 7B corresponds to an arrangement in which the bypass switch SW12 is controlled by counting the ON period of the bypass switch SW12 instead of detecting the locked state. In step S714, the clock generation circuit 400 is in a power down state of no power supply. In step S716, the power on signal S14 of the clock generation circuit 400 is asserted, power supply to the clock generation circuit 400 is started, and the clock generation circuit 400 changes to the initial state. The clock generation circuit 400 turns on the bypass switch SW12 upon asserting of the power on signal S14. Note that it is sufficient as long as the power on of the clock generation circuit 400 and the turning on of the bypass switch SW12 synchronously occur. It does not matter whether the operations occur simultaneously or if one of the operations occurs earlier.

The initial value of the control voltage is provided to the VCO 106 when the bypass switch SW12 changes to the ON state. This changes the control voltage to a value capable of oscillation, and the output signal S8 of the VCO 106 changes to a clock signal. In step S718, the clock generation circuit 400 determines whether a first predetermined period has elapsed since the bypass switch SW12 has been turned on. For example, the time counter 411 starts counting when the bypass switch SW12 is turned on. The time counter 411 determines that the first predetermined period has elapsed when the count value reaches a first predetermined value. The first predetermined period is set to be longer than the time necessary for the output of the clock generation circuit 400 to be locked. If it is determined that the first predetermined period has elapsed, the clock generation circuit 400 turns off the bypass switch SW12 in step S720. Since a frequency fluctuation occurs when the bypass switch SW12 is turned off, the clock generation circuit 400 determines, in step S722, whether a second predetermined period has elapsed since the bypass switch SW12 has been turned off. After the second predetermined period has elapsed, the clock generation circuit 400 changes to the stable oscillation state in step S724. Note that if the frequency fluctuation due to switching is small or if it is unnecessary to confirm whether the clock generation circuit 400 is locked, step S722 may be omitted.

FIG. 8B is a timing chart corresponding to the flowchart shown in FIG. 7B. From the top in FIG. 8B, the power on signal S14, a count signal S20 that controls the bypass switch SW12, the control signal S6, the oscillation frequency of the VCO 106, and the count value of the time counter 411 are shown. In FIG. 8B, the abscissa indicates a time, and the ordinate indicates a voltage level of a signal, a frequency, or a count value. High level corresponds to ON and low level corresponds to OFF in each of the power on signal S14 of the clock generation circuit 400 and the count signal S20. The voltage of the control signal S6 shows analog change.

At time t12, the power on signal S14 of the clock generation circuit 400 changes to high level, and the count signal S20 also changes to high level accordingly. When the count signal S20 changes to high level, the bypass switch SW12 is turned on, and an initial value of the control voltage is input to the VCO 106. The VCO 106 starts to oscillate upon receiving this initial value. In addition, the time counter 411 starts counting in response to the turning on of the bypass switch SW12. At time t13, the count value of the time counter 411 reaches the first predetermined value. Subsequently, at time t14, the count signal S20 changes from high level to low level. The bypass switch SW12 is turned off when the count signal S20 changes to low level, and the bypassing of the low-pass filter 105 ends. The time counter 411 starts counting accordingly. At time t15, the count value of the time counter 411 reaches the second predetermined value. The switching noise SN caused by turning off the bypass switch SW12 settles until time t15.

The clock generation circuit 400 according to the third modification has the same effects as those of the clock generation circuit 300 according to the second embodiment.

In addition, in the second embodiment, the low-pass filter 105 may be replaced by a band elimination filter such as a notch filter. The connection order of the loop filter 104 and the low-pass filter 105 may be reversed. Furthermore, the first variable divider 107 and the second variable divider 108 may also be fixed dividers, respectively, and may supply a frequency division clock by parallel connection instead of series connection.

The arrangements and operations of the clock generation circuits according to the embodiments have been described above. It is to be understood by those skilled in the art that these embodiments are examples, various modifications can be made for combinations of the constituent elements and processes, and these modifications fall within the scope of the present invention. Furthermore, it is possible to have a combination of the embodiments, a combination of the modifications, and a combination of the embodiments and the modifications. For example, the bypass switch SW12 described in the second embodiment may be incorporated in the clock generation circuit 100 according to the first embodiment.

The clock generation circuit has been described in each of the first and second embodiments. However, the present invention is not limited to this. The technical idea of the embodiments can be applied to an arbitrary signal generation circuit capable of feeding back a phase or frequency comparison result.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2016-085431, filed Apr. 21, 2016, which is hereby incorporated by reference herein in its entirety.

What is claimed is:

1. A signal generation circuit comprising:
a voltage controlled oscillator configured to generate a signal with a frequency corresponding to a control voltage;
a divider configured to generate a divided signal by dividing the frequency of the signal generated by the voltage controlled oscillator;
a phase comparator configured to compare a reference clock signal generated by a reference oscillator and the divided signal generated by the divider;
a charge pump configured to output a current corresponding to a comparison result of the phase comparator;
a loop filter configured to generate a voltage corresponding to the current output by the charge pump;
a switched capacitor filter configured to generate, by sampling the voltage generated by the loop filter, a control voltage of the voltage controlled oscillator in a steady state; and
an initial-value provision circuit configured to provide an initial value of the control voltage of the voltage controlled oscillator.

2. The circuit according to claim 1, wherein the initial-value provision circuit includes:
a switch having one terminal to which the initial value of the control voltage of the voltage controlled oscillator is applied and the other terminal to which an input terminal of the control voltage of the voltage controlled oscillator is connected; and
a control circuit configured to change the switch to an OFF state in the steady state and to turn on the switch in a period until the signal generation circuit reaches the steady state.

3. The circuit according to claim 2, wherein the control circuit turns on the switch upon powering on of the signal generation circuit.

4. The circuit according to claim 2, wherein the control circuit turns off the switch when the signal generated by the voltage controlled oscillator is locked.

5. The circuit according to claim 2, wherein the control circuit turns off the switch after a predetermined period has elapsed since the switch has been turned on.

6. The circuit according to claim 2, wherein the control circuit turns off the switch when the frequency of the signal generated by the voltage controlled oscillator exceeds a threshold.

7. The circuit according to claim 2, wherein the initial-value provision circuit further includes an initial-value generation circuit configured to generate the initial value of the control voltage of the voltage controlled oscillator, and
the initial value generated by the initial-value generation circuit is applied to the one terminal of the switch.

8. The circuit according to claim 2, wherein the voltage generated by the loop filter is applied to the one terminal of the switch.

9. The circuit according to claim 7, further comprising another switch having one terminal to which the voltage generated by the loop filter is applied and the other terminal to which the input terminal of the control voltage of the voltage controlled oscillator is connected.

10. The circuit according to claim 1, wherein the switched capacitor filter samples the voltage generated by the loop filter by using a sampling clock based on the signal generated by the voltage controlled oscillator.

11. A signal generation method comprising:
generating a signal with a frequency corresponding to a control voltage;
generating a divided signal by dividing a frequency of the generated signal;
comparing a reference clock signal generated by a reference oscillator and the divided signal;
outputting, from a charge pump, a current corresponding to the comparison result;
generating, by a loop filter, a voltage corresponding to the output current;
generating, by sampling the generated voltage, a control voltage of the voltage controlled oscillator in a steady state; and
providing an initial value of the control voltage of the voltage controlled oscillator.

12. A signal generation circuit comprising:
a voltage controlled oscillator configured to generate a signal with a frequency corresponding to a control voltage;
a divider configured to generate a divided signal by dividing a frequency of the signal generated by the voltage controlled oscillator;
a phase comparator configured to compare a reference clock signal generated by a reference oscillator and the divided signal generated by the divider;
a charge pump configured to output a current corresponding to the comparison result of the phase comparator;
a loop filter configured to generate a voltage corresponding to the current output by the charge pump;
a switched capacitor filter configured to generate, by sampling the voltage generated by the loop filter by the divided signal, the control voltage of the voltage controlled oscillator in a steady state; and
an initial-voltage provision circuit configured to provide, as an initial voltage of the control voltage, a voltage of a range in which the voltage controlled oscillator can generate a signal for a period until the steady state is reached.

13. The circuit according to claim 12, wherein the initial-voltage provision circuit includes:
a switch having one terminal to which the initial voltage of the control voltage of the voltage controlled oscillator is applied and the other terminal to which an input terminal of the control voltage of the voltage controlled oscillator is connected; and
a control circuit configured to change the switch to an OFF state in the steady state and to turn on the switch in a period until the signal generation circuit reaches the steady state.

14. The circuit according to claim 13, wherein the control circuit turns on the switch upon powering on of the signal generation circuit.

15. The circuit according to claim 13, wherein the control circuit turns off the switch when the signal generated by the voltage controlled oscillator is locked.

16. The circuit according to claim 13, wherein the control circuit turns off the switch after a predetermined period has elapsed since the switch has been turned on.

17. The circuit according to claim 13, wherein the control circuit turns off the switch when the frequency of the signal generated by the voltage controlled oscillator exceeds a threshold.

18. The circuit according to claim 12, wherein the switched capacitor filter samples the voltage generated by the loop filter by using a sampling clock based on the signal generated by the voltage controlled oscillator.

19. A signal generation method comprising:
generating, by a voltage controlled oscillator, a signal with a frequency corresponding to a control voltage;
generating a divided signal by dividing a frequency of the generated signal;
comparing a reference clock signal generated by a reference oscillator and the divided signal;
outputting, from a charge pump, a current corresponding to the comparison result;
generating, by a loop filter, a voltage corresponding to the output current;
generating, by sampling the generated voltage, a control voltage of the voltage controlled oscillator in a steady state; and
providing, as an initial voltage of the control voltage, a voltage of a range in which the voltage controlled oscillator can generate a signal for a period until the steady state is reached.
